(19) United States
(12) Patent Application Publication
(10) Pub. No.: US 2010/0198535 A1
(43) Pub. Date: Aug. 5, 2010

(54) POWER DISTRIBUTION UNIT MONITORING NETWORK AND COMPONENTS

(75) Inventors: Kenneth Brown, Chula Vista, CA (US); Carlos G. Ramirez, Chula Vista, CA (US); Mark A. Guymon, Everett, WA (US); Thomas Richard Schoepf, Everett, WA (US)

Correspondence Address: Davis Wright Tremaine LLP/Leviton, 1201 Third Avenue, Suite 2200, Seattle, WA, 98101, US

(73) Assignee: Leviton Manufacturing Co., Inc., Little Neck, NY (US)

(21) Appl. No.: 12/365,099

(22) Filed: Feb. 3, 2009

(51) Int. Cl. G01R 21/00

(52) U.S. Cl. 702/62

(57) ABSTRACT

A system to monitor power loading in a plurality of power distribution units. The system includes a power monitoring gateway with a port configured to communicate with an internet protocol network using an internet protocol address. The power monitoring gateway is also configured to communicate with the plurality of power distribution units through a communication link that does not use internet protocol addressing. The communication link in some embodiments is a wireless link. In other embodiments, the communication link uses a single pair of wires with the power monitoring gateway and the power distribution units configured in a daisy chain topology.

### BACKGROUND OF THE INVENTION

1. Field of the Invention

The present invention is directed generally to power distribution systems within a telecommunications facility or data center. In particular, the present invention is directed to networks to monitor power distribution systems.

2. Description of the Related Art

Power distribution units (PDU) are a necessary part of any data center or telecommunications facility. Mounted in an equipment rack, a PDU distributes power, typically AC power, to computing and communications equipment in the rack. Traditionally, PDUs have been simple devices. Typical PDUs included power receptacles, power inputs, and a few breakers and manually operated switches.

More recently, monitoring intelligence has been added to some PDUs. Some PDUs now have sensors to monitor a PDU load bank, including sensors for current, voltage and power. Some PDUs have displays that display power loading information. Some PDUs have network connections to transmit power loading information to a central monitoring facility. This allows personnel at the central monitoring facility to keep track of power loads for equipment at remote sites, detect problems before they become severe and troubleshoot problems once they occur. Such PDUs typically use Ethernet connections to communicate with other devices and are individually addressable with each PDU having its own internet protocol (IP) address. This can be an inefficient use of resources which requires more wiring, more computational resources in the PDU and more IP addresses.

### BRIEF DESCRIPTION OF THE SEVERAL VIEWS OF THE DRAWING(S)

FIG. 1 is a schematic drawing of a power distribution monitoring network and its components.

FIG. 2 is a schematic diagram showing a power monitoring network with wireless links.

FIG. 3 is a schematic diagram of one of the power distribution units from FIG. 1.

FIG. 4 is a schematic diagram of the power monitoring gateway 108 shown in FIG. 1.

FIG. 5 is a flow chart showing a method for communicating power loading information from a plurality of power distribution units.

In the Figures, various objects are identified with reference numbers. If there are multiple instances of the same object in a figure, they will be referred to by the same reference number but with a different suffix letter appended. In the following discussion, if a reference is made to a reference number that identifies multiple objects but without a suffix letter appended, then the reference is to all the multiple objects as a group.

### DETAILED DESCRIPTION OF THE INVENTION

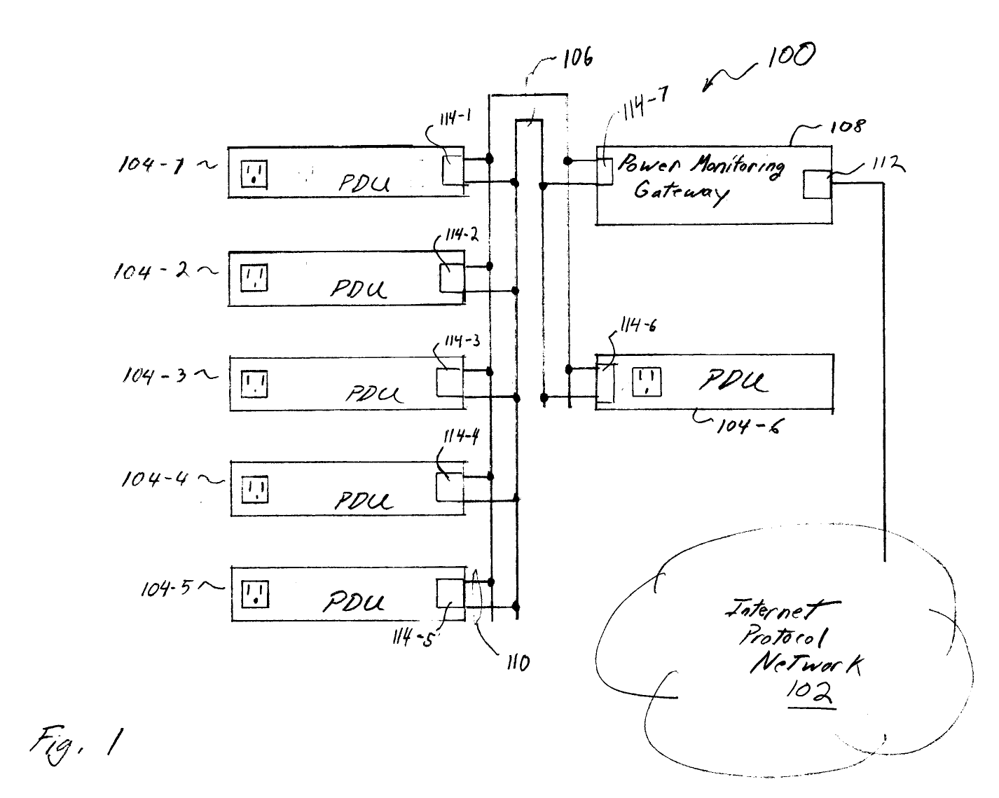

FIG. 1 is a schematic drawing of a power distribution monitoring network 100 and its components. The power monitoring network 100 is configured to monitor power loading in various devices, generate power loading information, send that power loading information to a gateway which in turn sends power loading information over an internet to a central monitoring point. Some of the components of the power monitoring network 100 may connect with an IP based network (“IP network”) 102. The power monitoring network 100 comprises a plurality of power distribution units (PDUs) 104-1 through 104-6, a power monitoring gateway 108 and a wire pair 106. All of the devices in the power monitoring network 100, both PDUs 104 and power monitoring unit 108, each have a wired communication port 114. Each wired communication port 114 in turn has a transmitter and receiver, both connected to a stub 110 conductor pair. The PDUs 104 and the power monitoring gateway 108 are described in greater detail in a later section herein.

The wire pair 106 serves as a communication link communicatively coupling the power monitoring gateway 108 and the PDUs 104 in a daisy chain topology. The wire pair 106 is typically a twisted wire pair. In some embodiments, the wire pair 106 may be untwisted. In yet other embodiments, the wire pair 106 may be replaced with a pair of conducting paths with a different construction, such as a pair of bus bars or strip lines. In some embodiments, the wire pair 106 comprises a series of jumper wires, each pair of jumper wires connecting the wired communication port 114 in one PDU 104 with the wired communication port 114 in a PDU 104 that is next in the daisy chain. For example, a pair of jumper wires may connect the wired communication port 114-5 of PDU 104-5 with the wired communication port 114-4 of PDU 104-4. Then a second pair of jumper wires connects the wired communication port 114-4 of PDU 104-4 with wired communication port 114-3 of PDU 104-3. In this fashion, a continuous conducting path can be formed from the power monitoring gateway 108 all the way to PDU 104-5.

In some embodiments, the wire pair 106 is part of a cable. In some embodiments, the cable has a ground. In some embodiments, the ground is a wire. In other embodiments, the ground is a shielding sheath that surrounds the wire pair 106.

The wire pair 106 connects the power monitoring gateway 108 and the PDUs 104 using a daisy chain topology as shown. The wired communication port 114 connects to the wire pair 106 through the stub 110 conductor pair. In the daisy chain topology, each transmitter and receiver pair is attached to the wire pair 106 as close as possible. Keeping the stub conductor pairs 110 as short as possible will enable the wire pair 106 to perform much like a single transmission line without stubs or branches. This minimizes reflections of signals within the wire pair 106 and improves performance of signal transmission and reception, particularly in terms of maximum bit rate and distance. The daisy chain topology for the wire pair 106 prevents a failure in a single PDU from interrupting communications between the power monitoring gateway 108 and the other non-failed PDUs 104.

The power monitoring gateway 108 may be in any position along the wire pair 106 relative to the PDUs 104. Power monitoring gateway 108 may be at the end of the wire pair 106, or it may be in a middle position on the wire pair 106, as shown in FIG. 1.

The power monitoring gateway 108 and the power distribution units 104 communicate with each other in a half-duplex mode. This is a cost savings as it allows the use of only a single wire pair, whereas full duplex would require two wire pairs. To facilitate the half-duplex mode, the power monitoring gateway 108 is configured as a network master unit and each of the PDUs 104 is configured as a network slave. The PDUs 104 are network slaves and do not initiate transmission of signals without permission from the master. Each of the PDUs 104 and the power monitoring gateway 108 are individually addressable using a simple addressing system known by all the components in the network 100. This system does not use IP addresses, which would require far more computational effort and expense. The power monitoring network 108 sends a token to one of the PDUs 104 in a communication when the power monitoring gateway 108 desires a response from the addressed PDU 104. After receiving a token, the PDU 104 then has a period of time in which to make a response.

The transmitters and receivers in the power monitoring gateway 108 and PDU 104 are configured to use differential signals to communicate. Differential signaling increases noise tolerance allowing for communications over longer distances and/or higher bit rates than would be achievable with non-differential signals.

In some embodiments, the receiver in the wired port 114 includes an input resistance over 10,000 ohms. This high input resistance ensures that the receiver does not put a significant current drain on any transmitter attached to wire pair 106. In some embodiments, wired communication port 114 includes a transmitter with a driver resistance of less than 75 ohms. This prevents an excessive amount of power from being dissipated in the transmitter when transmitting signals over the wire pair 106.

In some embodiments, the receivers and transmitters in the power monitoring gateway 108, the PDUs 104 and the wire pair 106 conform to the EIA-485 standard. The EIA-485 standard requires differential signaling, half-duplex operation and a shielded twisted pair cable.

In some embodiments, the transmitters and receivers in the power monitoring gateway 108 and PDUs 104 conform to the BACnet standard. BACnet is a data communications protocol for building automation and control networks. BACnet was designed to meet the communications needs of building automation control systems for applications such as heating, ventilation, air conditioning, lighting and fire detection systems. BACnet has rules for specifying communications media and data link layer protocols. BACnet has rules for modeling network devices using software objects. BACnet specifies use of several different physical and data link layer protocols including Ethernet, ARCnet, point-to-point (PTP) and a Master-Slave/Token Passing protocol (MS/TP) that is unique to BACnet. Choice of the MS/TP protocol requires use of the EIA-485 physical layer signaling standard. Most embodiments conform to the BACnet MS/TP protocol.

As configured, the power monitoring network allows power monitoring gateway 108 to communicate with the various PDUs 104 over the wire pair 106. The power monitoring gateway 108 is configured to request updates from a particular PDU on information regarding power loading of the PDU. Once a PDU receives a request for power loading information, the PDU is configured to send the power loading information requested back to power monitoring gateway 108. The power monitoring gateway 108 is configured to send the information to a central monitoring location via an IP port 112 and the IP network 102. With this configuration, only the power monitoring gateway 108 requires an IP address and the PDUs 104 do not have their own IP addresses or the hardware necessary for IP address processing.

In some embodiments, power monitoring gateway 108 may be communicatively connected through wire pair 106 to equipment of different types and functions than PDUs 104. Such equipment may include lighting, heating and cooling or fire detection. Such equipment must also conform to the same standards as the power monitoring network 100 which, in most embodiments, is the BACnet MS/TP standard.

The components of the power monitoring network 100, including the transmitters and receivers of the power monitoring gateway 108, the PDUs 104 and the wire pair 106, are configured to allow at least five PDUs 104 to communicatively connect to the power monitoring gateway 108. In embodiments fully compliant with BACnet and EIA-485, at least 31 PDUs 104 may be communicatively connected to the power monitoring gateway 108 over the wire pair 106 without any repeating device. With a repeating device, additional PDUs, beyond the 31 PDUs 104 for the non-repeating device configuration, may be added.

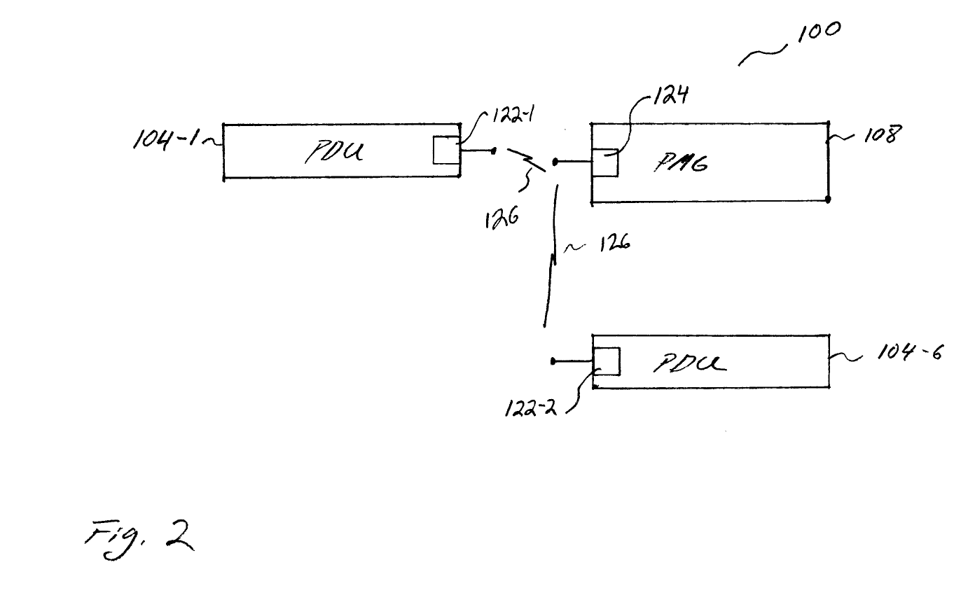

FIG. 2 is a schematic diagram showing a power monitoring network with wireless links. The power monitoring gateway 108 and the PDUs 104 are identical to the devices of the same number shown in FIG. 1 except for the addition of PDU wireless ports 122 in the PDUs 104 and gateway wireless port 124 in the power monitoring gateway 108. These wireless ports 122 and 124, may be incorporated into the PDUs 104 and power monitoring gateway 108 in addition to, or instead of, the wire pair 106 shown in FIG. 1. In some embodiments, the wireless ports 122 and 124 could be retrofitted internally to the PDUs 104 or the power monitoring gateway 108 or externally via an Ethernet port or USB port. The wireless ports 122 and 124 follow a wireless protocol such as Zigbee, Zwave, BACnet over Zigbee or BACnet over Z-Wave.

In some embodiments, the power monitoring gateway 108 may also be combined with the PDU 104 in a single device.

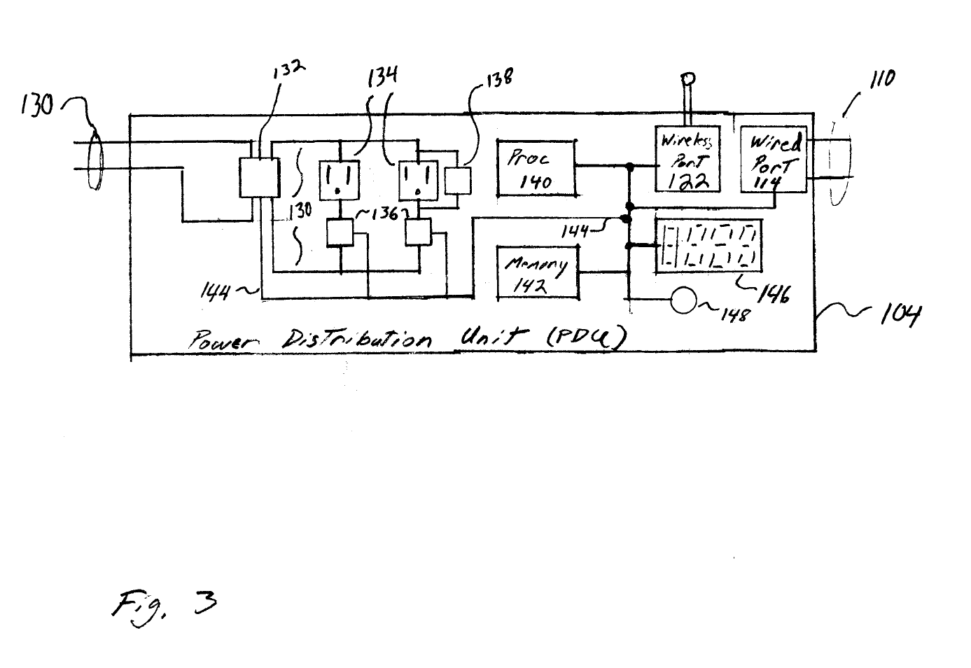

FIG. 3 is a schematic diagram of one of the PDUs 104 from FIG. 1. The PDU 104 has power leads 130 entering the device. Power leads 130 may be AC or DC, single phase or three phase. One or more circuit breakers 132 are placed in line with the power leads 130 and configured to control flow of power through the leads 130. One or more power receptacles 132 are connected to the power leads 130.

One or more current sensors 136 are placed in line with the power leads. In some embodiments, each receptacle 134 has its own associated current sensor 136 measuring current for just that receptacle 134. In other embodiments, the PDU 104 has only a single current sensor 136 measuring current to all receptacles 134. In yet other embodiments, the PDU 104 has groups of receptacles 134, with each group having a current sensor 136. For example, the PDU 104 may have groups that include all the receptacles 134 connected to a particular phase. Utilities or other power suppliers usually maintain a constant bus voltage. This means that power provided varies primarily with, and directly proportional to, the current. In these situations, power can be reliably monitored by a current sensor alone.

In some embodiments, a voltage sensor 138 is included in PDU 104. This allows for more accurate detection of power in situations where the bus voltage is likely to vary. The voltage sensor also allows calculation of power factor.

The PDU 104 includes a distribution unit processor 140 and a distribution unit memory 142. The distribution unit processor 140 is configured to execute control algorithms for operating PDU 104, particularly its monitoring functions and communications functions. The distribution unit processor 140 is configured to calculate additional power loading information including real power, apparent power and power factor based on measured power loading information and, in some embodiments, voltage. The distribution unit memory 142 is configured to store control algorithms and also provide storage for power loading information including measured and calculated power loading information. The display 146 is configured to display information including power loading information stored in the memory or reported real time from one of the sensors (i.e., 136 current sensor or voltage sensor 138). A toggle switch 148 is configured to generate control signals used by the processor to control the information displayed in the display 146. An internal communications bus 144 communicatively couples the distribution unit processor 140, the memory 142, the current sensor 136, the voltage sensor 138, the wireless port 122, the wired communication port 114, the circuit breaker 132, the display 146, and toggle switch 148.

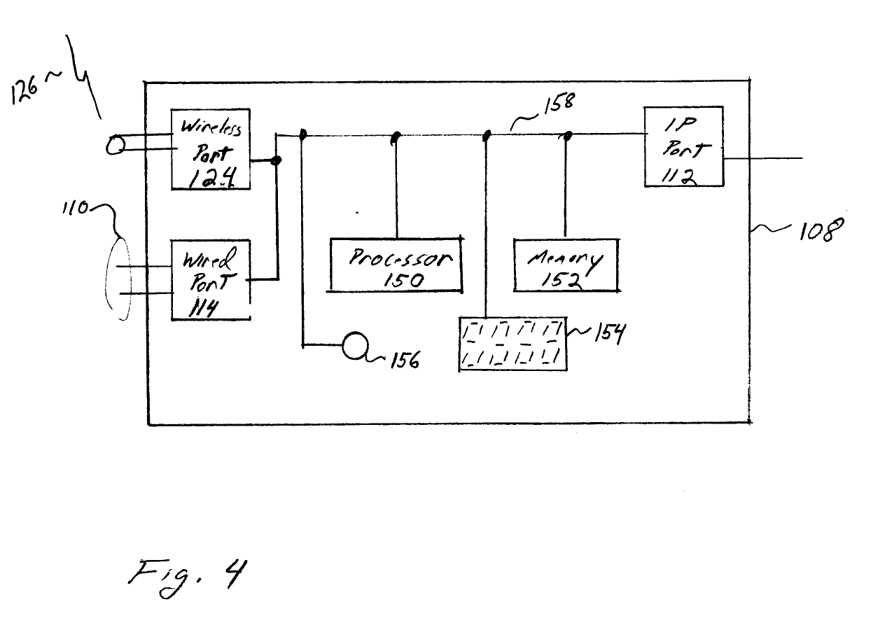

FIG. 4 is a schematic diagram of the power monitoring gateway 108 shown in FIG. 1. The power monitoring gateway 108 is shown with a single wired communication port 114. This wired communication port 114 is substantially the same as the wired communication port 114 in PDUs 104. In this embodiment, the power monitoring gateway 108 is shown with a single wired communication port 114. In other embodiments, the power monitoring gateway 108 may have a plurality of wired communication ports 114. Each of the plurality of wired communication ports 114 would be configured to be connected to an independent daisy chain of PDUs 104. The power monitoring gateway 108 has a wireless port 122 that has been described previously. This wireless port 122 is substantially identical to the wireless port in the PDUs 104. The wireless port 122 may be an integral component of the power monitoring gateway 108. In other embodiments, the wireless port 122 is a removable module that can be inserted into the power monitoring gateway 108. In yet other embodiments, the wireless port 122 is a separate device connected to the power monitoring gateway via short cable conforming to a standard such as Ethernet or USB. The power monitoring gateway 108 has an IP port 112 that has been described previously. The power monitoring gateway 108 has a gateway processor 150 and a gateway memory 152. The gateway processor 150 is configured to run control algorithms for operations of the power monitoring gateway including the communication ports 114,112 and wireless port 124. The gateway memory 152 is configured to provide storage for information received from the ports 114,112, and 122. The power monitoring gateway 108 has a display 154 configured to display information stored in the gateway memory 152. The power monitoring gateway 108 has a toggle switch 156 configured to provide simple controls for the power monitoring gateway 108 and, in particular, for controlling the display of information on the display 154.

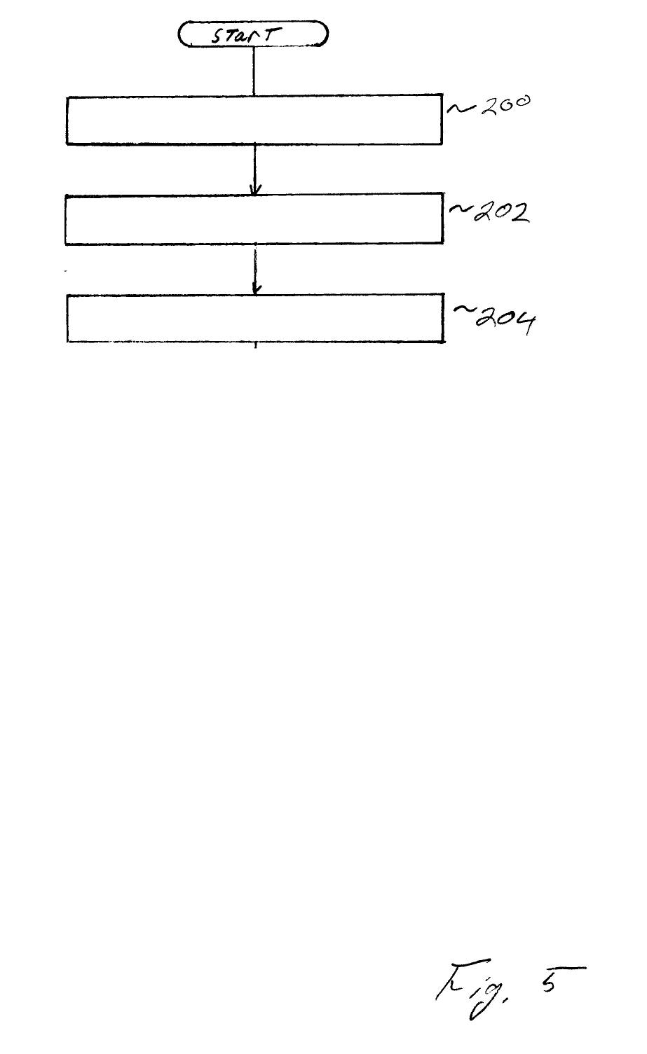

FIG. 5 is a flow chart showing a method for communicating power loading information from a plurality of power distribution units 104.

Step 200 requires sending a plurality of update messages over a communication link. Each of the plurality of update messages is from a different one of the plurality of power distribution units 104. Each of the plurality of update messages includes power loading information related to the respective power distribution unit. In some embodiments, sending the plurality of update messages over the communication link further comprises sending the plurality of update messages over a pair of conducting paths linking each of the plurality of power distribution units and the power monitor gateway in a daisy chain topology. In some embodiments, sending the plurality of update messages over the communication link further comprises sending the plurality of update messages using differential signals. In some embodiments, sending the plurality of update messages over the communication link further comprises sending the plurality of update messages over a communication link that conforms to a BACnet standard. In some embodiments, sending the plurality of update messages over the communication link further comprises sending the plurality of update messages over a wireless communications link.

Step 202 requires receiving the plurality of update messages at a power monitoring gateway 108.

Step 204 requires sending an internet protocol message from the power monitoring gateway over an internet protocol network, the internet protocol message including power loading information from each of the plurality of power distribution units.

The foregoing described embodiments depict different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality.

While particular embodiments of the present invention have been shown and described, it will be obvious to those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”) ; the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Accordingly, the invention is not limited except as by the appended claims.

The invention claimed is:

1. A power monitoring network comprising:
a plurality of power distribution units, wherein each of the plurality of power distribution units has an electrical receptacle, wherein each of the plurality of power distribution units is configured to measure current drawn by the electrical receptacle;
a power monitor gateway configured to communicate with the plurality of power distribution units and configured to communicate with an internet protocol network using an internet protocol address; and
a communication link configured to link the plurality of power distribution units and the power monitor gateway.

2. The power monitoring network of claim 1 wherein the communication link is configured to link at least five power distribution units and the power monitor gateway.

3. The power monitoring network of claim 1 wherein the communication link comprises a pair of conducting paths linking each of the plurality of power distribution units and the power monitor gateway in a daisy chain topology.

4. The power monitoring network of claim 2 wherein the communication link is configured to transmit and receive differential signals.

5. The power monitoring network of claim 1 wherein the power monitor is configured to be a network master and the plurality of power distribution units configured to be network slaves.

6. The power monitoring network of claim 1 wherein the communication link conforms to an EIA-485 standard.

7. The power monitoring network of claim 1 wherein the communication link conforms to a BACnet standard.

8. The power monitoring network of claim 1 wherein the communication link is a wireless communications link.

9. The power monitoring network of claim 1 wherein each of the plurality of power distribution units does not have hardware to process an internet protocol address.

10. A power distribution unit comprising:
an electrical receptacle;
a current sensor coupled with the electrical receptacle and configured to generate measurements of current drawn by the electrical receptacle;
a communication port communicatively coupled with the current sensor and configured to communicate with a power monitor gateway using differential signals over a wire pair.

11. The power distribution unit of claim 10 further comprising a wireless transceiver coupled with the current sensor and configured to communicate with the power monitor gateway.

12. The power distribution unit of claim 10 wherein the communication port is further configured to communicate over a wire pair that is within a cable that has a ground.

13. The power distribution unit of claim 10 wherein the communication port is further configured to communicate over a wire pair shared with a plurality of other power distribution units in a daisy chain topology.

14. The power distribution unit of claim 10 wherein the communication port is further configured to communicate with the power monitor gateway in a half-duplex mode.

15. The power distribution unit of claim 10 wherein the communication port is further configured to be a network slave and configured to recognize the power monitor gateway as a network master.

16. The power distribution unit of claim 10 wherein the communication port further comprises a receiver with an input resistance of over 10 kΩ.

17. The power distribution unit of claim 10 wherein the communication port further comprises a transmitter with driver resistance of under 75Ω.

18. The power distribution unit of claim 10 wherein the communication port conforms to an EIA-485 standard.

19. The power distribution unit of claim 10 wherein the communication port conforms to a BACnet standard.

20. A power distribution unit comprising:
an electrical receptacle;
a current sensor coupled with the electrical receptacle and configured to generate measurements of current drawn by the electrical receptacle;
a communication port communicatively coupled with the current sensor and configured to communicate with a power monitor gateway over a pair of conducting paths shared with a plurality of other power distribution units.

21. The power distribution unit of claim 20 wherein the communication port is further configured to communicate over a pair of conducting paths with the plurality of other power distribution units connected to the pair of conducting paths in a daisy chain topology.

22. The power distribution unit of claim 21 wherein the communication port is further configured to communicate with the power monitor gateway in a half-duplex mode.

23. The power distribution unit of claim 22 wherein the communication port is further configured to communicate using differential signals.

24. The power distribution unit of claim 23 wherein the communication port is further configured to be a network slave and configured to recognize the power monitor gateway as a network master.

25. The power distribution unit of claim 24 wherein the communication port conforms to an EIA-485 standard.

26. The power distribution unit of claim 25 wherein the communication port conforms to a BACnet standard.

27. A power distribution unit comprising:
an electrical receptacle;
a current sensor coupled with the electrical receptacle and configured to generate measurements of current drawn by the electrical receptacle; and
a communication port communicatively coupled with the current sensor and configured to communicate with a power monitor gateway using differential signals over a single pair of conducting paths configured in a daisy chain topology with a plurality of other power distribution units.

28. The power distribution unit of claim 27 wherein the communication port conforms to the EIA-485 standard.

29. The power distribution unit of claim 27 wherein the communication port conforms to a BACnet standard.

30. The power distribution unit of claim 27 wherein the communication port is further configured to communicate over the single pair of conducting paths configured in a daisy chain topology with at least five power distribution units.

31. A power monitoring gateway comprising:
a first communication port configured to communicate with an internet protocol network using an internet protocol address associated with the power monitoring gateway;
a second communication port communicatively coupled with first communication port and configured to communicate with a plurality of power distribution units by transmitting and receiving differential signal units over a single pair of conducting paths connecting the power monitoring gateway and the plurality of power distribution units in a daisy chain topology.

32. The power distribution unit of claim 31 wherein the second communication port conforms to an EIA-485 standard.

33. The power distribution unit of claim 32 wherein the second communication port conforms to a BACnet standard.

34. A method for communicating power loading information from a plurality of power distribution units comprising:
sending a plurality of update messages over a communication link, each of the plurality of update messages from a different one of the plurality of power distribution units, wherein each of the plurality of update messages includes power loading information related to the respective power distribution unit;
receiving the plurality of update messages at a power monitoring gateway; and
sending an internet protocol message from the power monitoring gateway over an internet protocol network, the internet protocol message including power loading information from each of the plurality of power distribution units.

35. The method of claim 34 further comprising configuring the communication link to communicatively couple at least five power distribution units and the power monitor gateway.

36. The method of claim 34 wherein sending the plurality of update messages over the communication link further comprises sending the plurality of update messages over a pair of conducting paths linking each of the plurality of power distribution units and the power monitor gateway in a daisy chain topology.

37. The method of claim 34 wherein sending the plurality of update messages over the communication link further comprises sending the plurality of update messages using differential signals.

38. The method of claim 34 wherein sending the plurality of update messages over the communication link further comprises sending the plurality of update messages over a communication link that conforms to a BACnet standard.

39. The method of claim 34 wherein sending the plurality of update messages over the communication link further comprises sending the plurality of update messages over a wireless communications link.

40. The method of claim 34 for use with a plurality of power distribution units that do not have hardware to process an internet protocol address wherein sending the plurality of update messages over the communication link further comprises sending the plurality of update messages from the power distribution units that do not have hardware to process an internet protocol address.
